(19) United States
(12) Patent Application Publication
(10) Pub. No.: US 2026/0082850 A1
(43) Pub. Date: Mar. 19, 2026

(54) SUBSTRATE PROCESSING APPARATUS AND SUBSTRATE PROCESSING METHOD

(71) Applicant: EUGENE TECHNOLOGY CO., LTD., Yongin-si, Gyeonggi-do (KR)

(72) Inventors: Jun Jin HYON, Yongin-si, Gyeonggi-do (KR); Joo Hyun CHO, Yongin-si, Gyeonggi-do (KR); Gyo Seong SEO, Yongin-si, Gyeonggi-do (KR); Yong Tak JIN, Yongin-si, Gyeonggi-do (KR)

(73) Assignee: EUGENE TECHNOLOGY CO., LTD., Yongin-si, Gyeonggi-do (KR)

(21) Appl. No.: 19/108,844

(22) PCT Filed: Jun. 30, 2023
(86) PCT No.: PCT/KR2023/009229

§ 371 Date: Mar. 5, 2025

(30) Foreign Application Priority Data
Sep. 5, 2022 (KR) 10-2022-0112232

(51) Int. Cl. H10P 72/00

(52) U.S. Cl. CPC H10P 72/0602; H10P 72/0431; H10P 74/238

(57) ABSTRACT

According to an embodiment of the present invention, a method for processing a substrate through a heater that heats the substrate to perform a semiconductor process, the method comprising: inputting, into a correlation formula of at least one independent variable, which is a parameter related to the heater, and a dependent variable including a measured temperature of the heater, a measurement value corresponding to the independent variable, and calculating a predicted temperature of the heater; and applying a Kalman filter to the predicted temperature to calculate an estimated temperature.

### TECHNICAL FIELD

The present invention relates to a substrate processing apparatus and a substrate processing method, and more particularly, to a substrate processing apparatus and a substrate processing method capable of checking the temperature of each zone of a heater.

### BACKGROUND ART

Generally, heaters used in semiconductor equipment are multi-zone, that is, composed of a plurality of zones (each zone has a heating wire installed independently). However, it is difficult to mount as many temperature sensors (TCs) as the number of zones. Specifically, the heater has a circular structure, and the number of zones that can measure/control the temperature is limited to one or two (for example, only the temperature in a part of the heater, that is, the center, can be measured). Therefore, when divided into more zones, the problem occurs that temperature sensors capable of measuring/controlling the temperature of each zone cannot be mounted.

Therefore, the output of other zones is ratio-controlled based on the output of controllable zone. However, this may cause problems in temperature verification or process results, and it takes a lot of time for temperature tuning.

In particular, since the semiconductor process generally depends on the temperature of the heater, it is important to measure/control the temperature of each area of the heater, and the above problems adversely affect the process uniformity of the substrate. In the manufacture of semiconductor devices, processing precision of about several nanometers is required according to the miniaturization and high functionalization of recent semiconductor devices. In order to realize such processing precision, a technology for realizing a stable semiconductor process by uniformly maintaining the temperature of the heater is required.

### DISCLOSURE OF THE INVENTION

### Technical Problem

The present invention provides a substrate processing apparatus and a substrate processing method capable of checking the temperature of each zone of the heater.

The present invention also provides a substrate processing apparatus and a substrate processing method capable of improving the utilization rate of equipment by reducing the time required for temperature tuning.

Further another object of the present invention will become more apparent from the following detailed descriptions and accompanying drawings.

### Technical Solution

According to an embodiment of the present invention, a method for processing a substrate through a heater that heats the substrate to perform a semiconductor process, the method comprising: inputting, into a correlation formula of at least one independent variable, which is a parameter related to the heater, and a dependent variable including a measured temperature of the heater, a measurement value corresponding to the independent variable, and calculating a predicted temperature of the heater; and applying a Kalman filter to the predicted temperature to calculate an estimated temperature.

The method may further comprising: storing the independent variable and the dependent variable in association with each other in a database; and calculating a coefficient included in the correlation formula through regression analysis on the independent variable and the dependent variable.

The heater may include first to n-th zones (n=2, 3, . . . , m, m is an integer), wherein the independent variable includes at least one of a temperature of any one of the first to n-th zones, a power ratio of the first to n-th zones, a current value supplied to a heating wire installed in a zone for which the predicted temperature is to be calculated, a resistance value for another one of the first to n-th zones, and a resistance value for a zone for which the predicted temperature is to be calculated.

The parameter may be a voltage value, a current value, a temperature value, a resistance value, a power value, a power ratio, an output, or the like.

Any one of the first to n-th zones may be a circular area located in the center of the heater.

Another one of the first to n-th zones may be a ring-shaped area surrounding any one of the first to n-th zones.

The correlation formula for calculating the predicted temperature (Tn) for the n-th zone may be expressed by the following <Mathematical Formula 1>:

$$Predicted Temperature ( Tn ) = Y - intercept + ( Temperature of any one of the first to n - th zones * a ) + ( Power ratio of the first zone * b 1 ) + ( Power ratio of the second zone * b 2 ) + … + ( Power ratio of the n - th zone * bn ) + ( Current value supplied to the heating wire installed in the n - th zone * c ) + ( Resistance value for the other one of the first to n - th zones * d ) + ( Resistance value for the n - th zone * e ) \qquad 〈 Mathematical Formula 1 〉$$

in Mathematical Formula 1, Y-intercept, a, b, c, d, and e are the coefficients.

The method may further comprising: placing a wafer TC capable of measuring the temperature of the first to n-th zones on the heater and acquiring the measured temperature.

According to an embodiment of the present invention, an apparatus for processing a substrate through a heater that heats the substrate to perform a semiconductor process, comprising: a database storing at least one independent variable and a dependent variable in association with each other; a correlation formula storage unit storing a correlation formula of the independent variable and the dependent variable; a calculation unit calculating a coefficient included in the correlation formula through regression analysis on the independent variable and the dependent variable; a temperature control mechanism including a Kalman filter calculating an estimated temperature from a predicted temperature; and a measuring mechanism acquiring a measurement value corresponding to the independent variable, wherein the calculation unit inputs the measurement value into the correlation expression and calculates the predicted temperature of the heater.

### Advantageous Effects

According to an embodiment of the present invention, the temperature of each zone of the heater can be checked without installing a temperature measuring device in each zone. This allows for feedback control of each zone and enables high-precision semiconductor processing.

### DESCRIPTION OF DRAWINGS

FIG. 1 is a schematic diagram illustrating a substrate processing apparatus according to an embodiment of the present invention.

FIG. 2 is a diagram illustrating the heater illustrated in FIG. 1.

FIG. 3 is a block diagram illustrating the temperature control mechanism illustrated in FIG. 1.

FIG. 4 is a flowchart illustrating a process of calculating an estimated temperature through the temperature control mechanism illustrated in FIG. 3 and the measuring mechanism.

FIG. 5 is a graph illustrating a change in the measured temperature of the first zone before and after application of the Kalman filter illustrated in FIG. 3.

FIG. 6 is a diagram illustrating a change in the RMSE value for the first zone before and after application of the Kalman filter illustrated in FIG. 3.

FIG. 7 is a diagram illustrating changes in the measured temperature and estimated temperature for the first zone after applying the Kalman filter illustrated in FIG. 3.

FIG. 8 is a diagram illustrating the estimated temperature illustrated in FIG. 4 and the actual temperature for each zone of the heater.

### BEST MODE

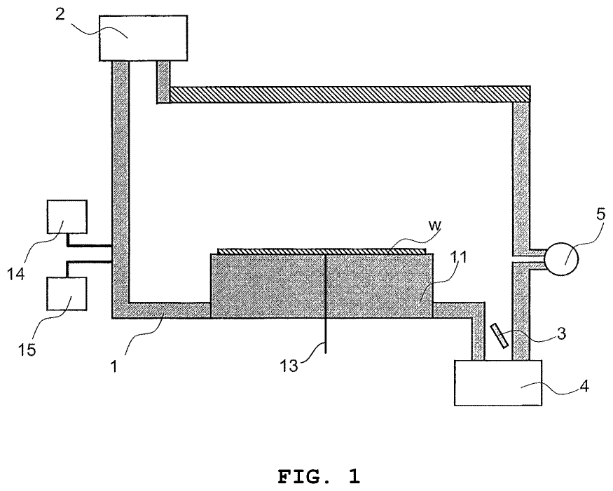

Hereinafter, preferred embodiments of the present invention will be described in more detail with reference to the accompanying drawings FIGS. 1 to 8. The embodiments of the present invention can be modified in various forms, and the scope of the present invention should not be interpreted as being limited to the embodiments described below. These embodiments are provided to more fully explain the present invention to those skilled in the art. Therefore, the shapes of elements in the drawings may be exaggerated to emphasize clearer description.

FIG. 1 is a schematic diagram illustrating a substrate processing apparatus according to an embodiment of the present invention. As shown in FIG. 1, the substrate processing apparatus has a processing chamber 1 in which a processing process is performed on an object to be processed, and a gas supply means 2 supplies gas into the processing chamber 1. The gas in the processing chamber 1 is exhausted through a gas exhaust means 4, and a valve 3 controls the amount of exhaust to control the pressure in the processing chamber 1. A pressure gauge 5 measures the pressure in the processing chamber 1.

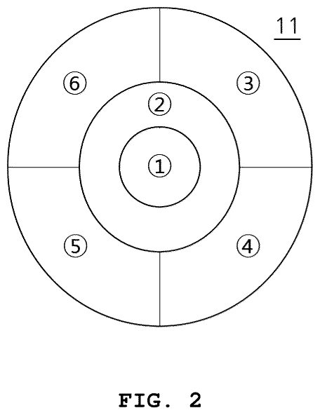

FIG. 2 is a diagram illustrating the heater illustrated in FIG. 1. The heater 11 is installed in the processing chamber 1 to support the object to be processed, and the heater 11 can be divided into six zones, first zone to sixth zone (\textcircled{1}-\textcircled{6}). Heating wires (not shown) are respectively installed in each of the divided zones and are independently controlled through a power supply mechanism (not shown). At this time, the power supply mechanism can supply power to each heating wire according to a certain ratio (or power ratio, for example, %) relative to the power supplied to the entire heater 11.

The first zone (\textcircled{1}) may be a circular area located in the center of the heater (11), and the second zone (\textcircled{2}) may be a ring-shaped area arranged around the first zone. The third to sixth zones (\textcircled{3}-\textcircled{6}) may be areas obtained by dividing a ring-shaped area arranged around the second zone into equal angles (for example, 90 degrees). However, unlike this embodiment, the heater 11 may be divided into five or fewer zones or seven or more zones, or may be divided into six zones through a method different from the above.

The temperature control mechanism 14 and the measuring mechanism 15 are provided to control the temperature of the heater 11. The measuring mechanism 15 includes a TC 21 installed in the first zone (\textcircled{1}) of the heater 11 for measuring the temperature of the first zone (\textcircled{1}) of the heater 11. In addition, as described below, the measuring mechanism 15 includes a temperature measuring sensor (for example, wafer TC(w)) corresponding to a temperature measuring unit. The temperature measuring sensor (for example, wafer TC(w)) is installed on the upper part of the heater 11, and includes thermocouples (TCs) installed to correspond to points located in each zone of the heater 11. A thermocouple wire (TC wire) connected to each thermocouple (TC) is connected to the temperature control mechanism 14, enabling temperature measurement for each zone.

The measuring mechanism 15 further includes a power measuring unit/current measuring unit/resistance measuring unit, and the power measuring unit/current measuring unit/resistance measuring unit measure the current power/current/resistance for each zone of the heater 11.

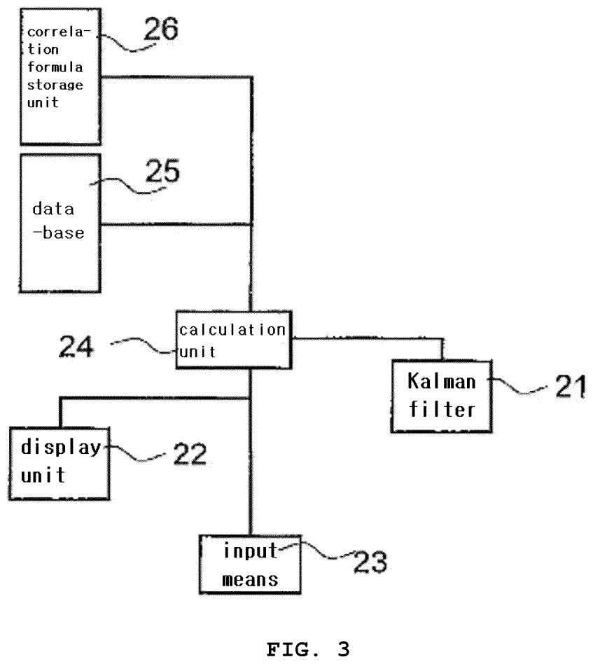

FIG. 3 is a block diagram illustrating the temperature control mechanism illustrated in FIG. 1. The values obtained by measuring the temperature/power/current/resistance for each zone of the heater 11 through the measuring mechanism 15 are transmitted to the temperature control mechanism 14, and the temperature control mechanism 14 estimates the temperature for each zone of the heater 11 from the values. The temperature control mechanism 14 includes a calculation unit 24, a display unit 22, a data input means 24, a database 25, a correlation formula storage unit 26, and a Kalman filter 21.

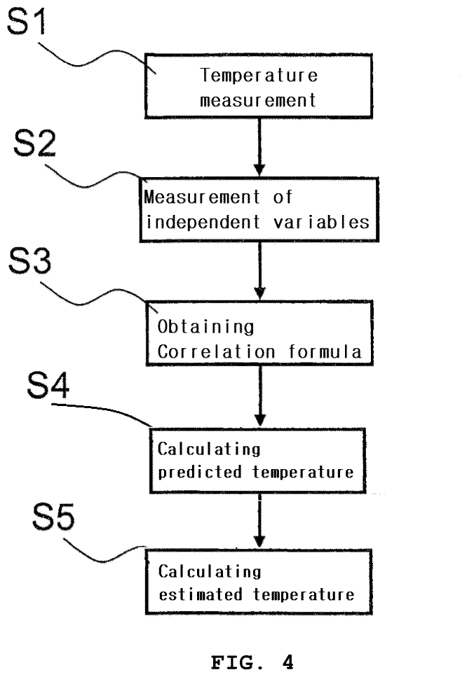

FIG. 4 is a flowchart illustrating a process of calculating an estimated temperature through the temperature control mechanism illustrated in FIG. 3 and the measuring mechanism. Hereinafter, with reference to FIG. 4, a temperature control method using the temperature control mechanism and the measuring mechanism will be described.

First, a temperature measuring sensor (for example, wafer TC(w)) is installed on the heater 11, and the temperature measuring sensor (for example, wafer TC(w)) has a wafer shape and can measure the temperature at a point located in each zone of the heater 11 (S1). The heater 11 is heated under various learning conditions (for example, heating conditions, stabilization, disturbance, etc.) for a sufficiently long time to measure the temperature for each zone of the heater 11. At the same time, learning conditions such as power/current/resistance for each zone of the heater 11 (for example, heating conditions, stabilization, disturbance, etc.) (for example, power measurement value/current measurement value/resistance measurement value) are also measured together (S2). The measurement temperature and learning conditions (for example, heating conditions, stabilization, disturbance, etc.) at this time are input/stored in the database 25 via the data input means 24.

The data input means 24 may be a device that can be manually input by an operator, for example, a keyboard, a mouse, or a touch pen, but a media drive capable of reading electronic information such as a floppy disk drive is suitable, and even more preferably, a network interface that automatically reads the measurement temperature and learning conditions (for example, heating conditions, stabilization, disturbance, etc.).

After these data are sufficiently accumulated in the database (25), the calculation unit (24) performs calculations to correlate the measurement temperature with the learning conditions (for example, heating conditions, stabilization, disturbance, etc.) to obtain a correlation formula. Here, in order to create a correlation formula, for example, a polynomial of the predicted temperature with learning conditions (for example, heating conditions, stabilization, disturbance, etc.) as variables may be assumed, and regression analysis may be performed to obtain each proportionality coefficient.

Specifically, in the x-th experiment, the temperature of each zone of the heater 11 is measured based on learning conditions (for example, heating conditions, stabilization, disturbance, etc.), and at the same time, learning conditions (for example, heating conditions, stabilization, disturbance, etc.) such as power/current/resistance are directly output from the measuring mechanism 15 to the database 25 and stored in association with the temperature of each zone of the heater 11.

In this way, when a data set of the measurement temperature and learning conditions (for example, heating conditions, stabilization, disturbance, etc.) for each zone is obtained, a correlation formula as shown below can be obtained from the data set (S3). It can be seen that the predicted temperature can be obtained from the learning conditions (for example, heating conditions, stabilization, disturbance, etc.) through the correlation formula. That is, the correlation formula for calculating the predicted temperature (Tn) for the n-th zone is expressed as <Mathematical Formula 1> below.

$$Predicted Temperature ( Tn ) = Y - intercept + ( Temperature of any one of the first to n - th zones * a ) + ( Power ratio of the first zone * b 1 ) + ( Power ratio of the second zone * b 2 ) + … + ( Power ratio of the n - th zone * bn ) + ( Current value supplied to the heating wire installed in the n - th zone * c ) + ( Resistance vlaue for the other one of the first n - th zones * d ) + ( Resistance value for the n - th zone * e ) \qquad 〈 Mathematical Formula 1 〉$$

In Mathematical Formula 1, Y-intercept, a, b, c, d, and e are the coefficients.

Specifically, the regression analysis can use the learning conditions (e.g., heating conditions, stabilization, disturbances, etc.) (specifically, the temperature of the first zone (\textcircled{1}), the power ratio for the first to sixth zones (\textcircled{1}-\textcircled{6}), the current value for the zone, the resistance value of the second zone (\textcircled{2}), and the resistance value of the zone) of the heater 11, as independent variables and the measured temperature of the zone as a dependent variable. The regression analysis may be SVM regression analysis, linear regression analysis, Gaussian regression analysis, or the like. Also, according to the above correlation formula, it can be seen that the predicted temperature is a proportionality coefficient for the learning conditions (e.g., heating conditions, stabilization, disturbances, etc.), and the calculation unit 24 calculates the proportionality coefficient from the data set.

In this way, a correlation formula for calculating the predicted temperature can be determined, and unlike this embodiment, the correlation formula may vary depending on the structure of the heater 11 (e.g., the arrangement of divided zones). In addition, the accuracy of the correlation formula can be increased through a polynomial including higher-order terms such as quadratic and cubic terms.

In performing such calculations, the calculation unit 24 may be a central processing unit or the like adopted in a general personal computer or the like, or may be an integrated circuit specialized for such types of calculations. After creating the correlation formula in this way, the correlation formula is recorded in the correlation formula storage unit 26.

After these series of operations are completed, the temperature measuring sensor (e.g., wafer TC(w)) installed on the heater 11 is removed. Now, although a temperature measuring device is not installed in the substrate processing apparatus, by measuring the learning conditions (e.g., heating conditions, stabilization, disturbances, etc.), the predicted temperature for each zone of the heater can be calculated from the correlation formula recorded in the correlation formula storage unit 26. By storing the correlation formula created in this way in the correlation formula storage unit 26 and reading it from the correlation formula storage unit 26 as necessary, the predicted temperature for each zone of the heater can be calculated (S4).

Meanwhile, the measured value read through the measuring mechanism 15 has noise that not only affects accuracy but also generates spikes, and the Kalman filter 21 can intelligently estimate the actual state of the system. This estimation is performed by Kalman's gain (often denoted as ‘K’).

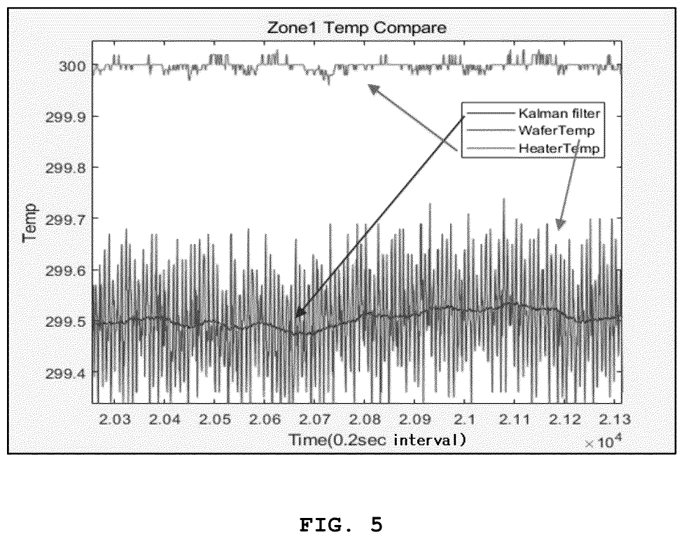

FIG. 5 is a graph illustrating a change in the measured temperature of the first zone before and after application of the Kalman filter illustrated in FIG. 3. As shown in FIG. 5, for the first zone (\textcircled{1}), the measured temperature (WaferTemp) through the temperature measuring sensor (for example, wafer TC(w)) has noise, and the value (Kalman filter) obtained by applying the Kalman filter to the measured temperature (WaferTemp) shows a similar trend to the measured temperature (HeaterTemp) through TC 21 and has a certain error.

In conclusion, the predicted temperature calculated through the temperature control mechanism 14 is input to the Kalman filter, and the Kalman filter can calculate the estimated temperature from the predicted temperature (S5). Specifically, it is as follows.

$$x\_Predict = ( A * Xk ) + B\_uk \qquad ( 1 ) System state equation$$

*A is the time for measuring temperature change and is the same every time, so it is 1
Xk is the initial value (changed later by calculation)
B_uk is an input value unrelated to the system and is 0 in temperature.

$$p\_Predict = ( A * Pk ) + Q \qquad ( 2 ) Error covariance$$

Pk is a value for uncertainty and uses 1 (that is, assumes that uncertainty is almost 0)
   Q is an element that gives weight, meaning that the larger Q is, the more weight is given to the measured value than the estimated value.

$$K\_gain = p\_Predict / ( H * p\_Predict + R ) \qquad ( 3 ) Kalman gain ( Kalman gain )$$

H is the conversion coefficient, R is the variance for the observed value

$$Xk = x\_Predict + K\_gain * ( z\_Din - x\_Predict ) \qquad ( 4 ) Estimation calculation$$

z_Din is the current measured value

$$Pk = ( 1 - K\_gain ) * p\_Predict \qquad ( 5 ) Error covariance update$$

Indicates the degree of correlation between the error of the predicted value and the Kalman gain

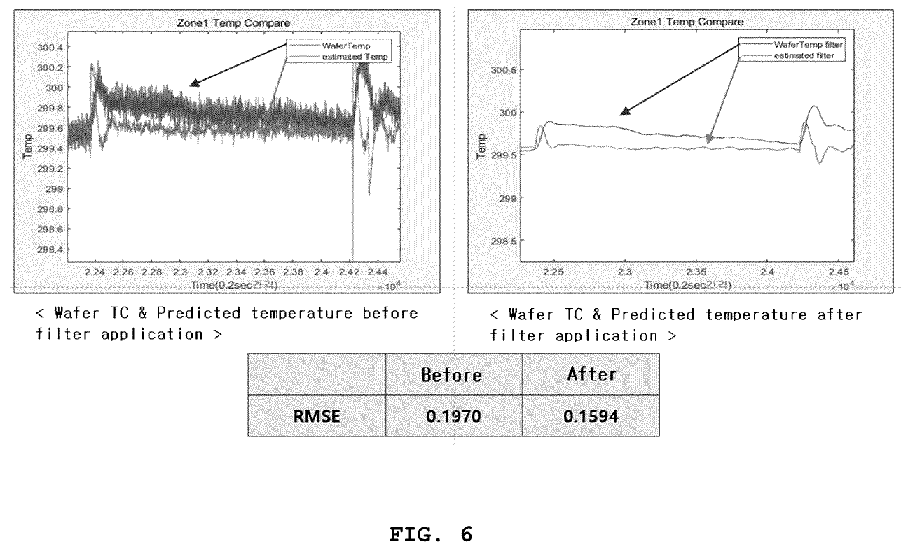

FIG. 6 is a diagram illustrating a change in the RMSE value for the first zone before and after application of the Kalman filter illustrated in FIG. 3. In FIG. 6, the left side is a graph showing the change in the measured temperature and the predicted temperature using a temperature measuring sensor (for example, wafer TC(w)) for the first zone, and the right side is a graph showing the change in the measured temperature and the predicted temperature after applying the Kalman filter. Looking at the RMSE (Root Mean Square Error) for each, it can be seen that the prediction accuracy (RMSE) is improved when the Kalman filter is applied.

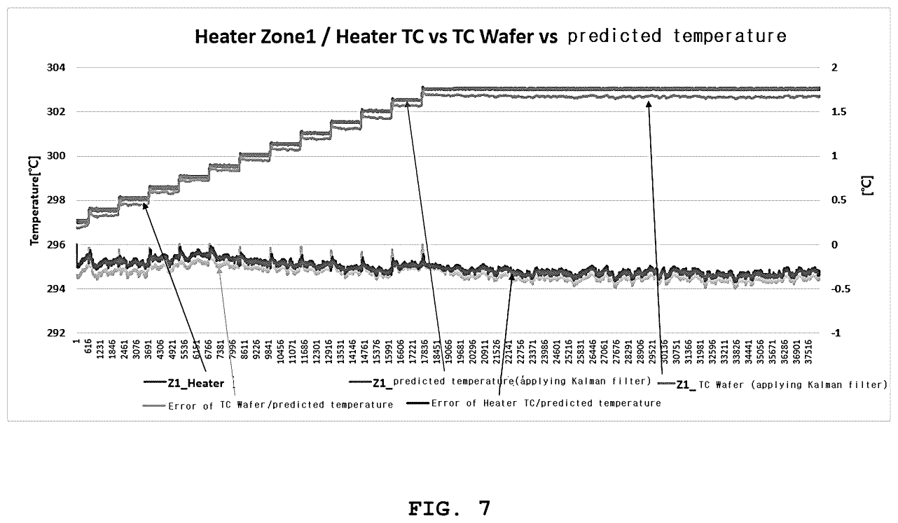

FIG. 7 is a diagram illustrating changes in the measured temperature and estimated temperature for the first zone after applying the Kalman filter illustrated in FIG. 3. As shown in FIG. 7, it can be seen that the measured temperature (TC Wafer temperature) has a similar trend to the estimated temperature (predicted temperature) and has a certain error, and the error is less than 0.5 degrees.

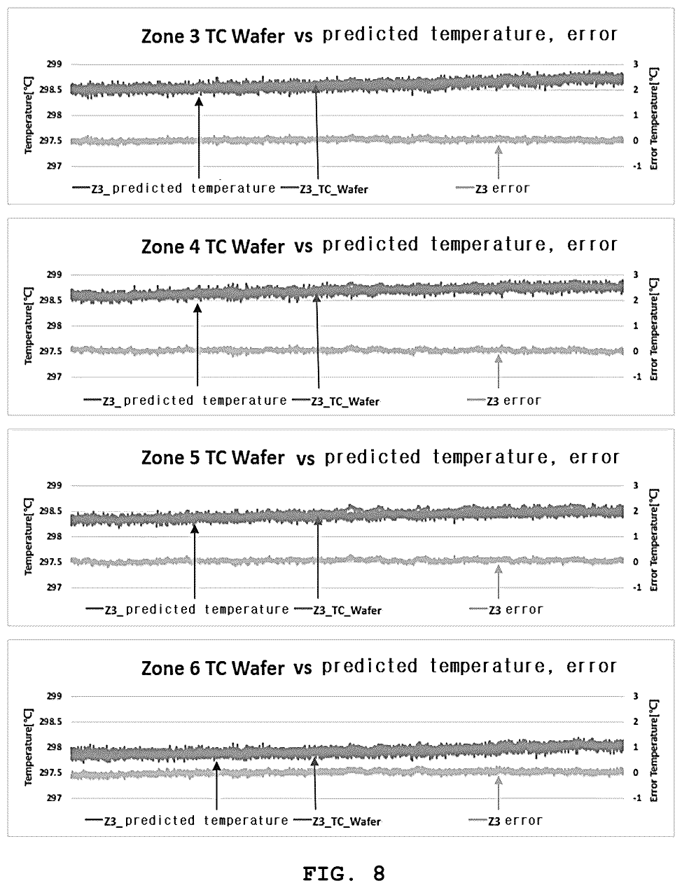

FIG. 8 is a diagram illustrating the estimated temperature illustrated in FIG. 4 and the actual temperature for each zone of the heater. As shown in FIG. 8, it can be seen that the change in the estimated temperature (predicted temperature) has a constant linearity with the change in the process result (thickness of the thin film).

The method of calculating the estimated temperature for each zone of the heater 11 using the learning conditions (for example, heating conditions, stabilization, disturbance, etc.) of the heater 11 has been described above, but the estimated temperature can be calculated through learning conditions other than the learning conditions (for example, heating conditions, stabilization, disturbance, etc.) described above.

As described above, according to the embodiment of the present invention, the temperature can be checked without installing a temperature measuring device in each zone of the heater 11, and the temperature control of the heater 11 can be optimized accordingly.

The present invention has been described in detail through preferred embodiments, but embodiments in other forms are also possible. Therefore, the technical spirit and scope of the claims described below are not limited to the preferred embodiments.

### INDUSTRIAL APPLICABILITY

The present invention can be applied to various types of semiconductor manufacturing equipment and manufacturing methods.

1. A method for processing a substrate through a heater that heats the substrate to perform a semiconductor process, the method comprising:
inputting, into a correlation formula of at least one independent variable, which is a parameter related to the heater, and a dependent variable including a measured temperature of the heater, a measurement value corresponding to the independent variable, and calculating a predicted temperature of the heater; and
applying a Kalman filter to the predicted temperature to calculate an estimated temperature.

2. The method of claim 1, further comprising:
storing the independent variable and the dependent variable in association with each other in a database; and
calculating a coefficient included in the correlation formula through regression analysis on the independent variable and the dependent variable.

3. The method of claim 1, wherein the heater includes first to n-th zones (n=2, 3, . . . , m, m is an integer),
wherein the independent variable includes at least one of a temperature of any one of the first to n-th zones, a power ratio of the first to n-th zones, a current value supplied to a heating wire installed in a zone for which the predicted temperature is to be calculated, a resistance value for another one of the first to n-th zones, and a resistance value for a zone for which the predicted temperature is to be calculated.

4. The method of claim 3, wherein any one of the first to n-th zones is a circular area located in the center of the heater.

5. The method of claim 4, wherein another one of the first to n-th zones is a ring-shaped area surrounding any one of the first to n-th zones.

6. The method of claim 3, wherein the correlation formula for calculating the predicted temperature (Tn) for the n-th zone is expressed by the following <Mathematical Formula 1>:
$$Predicted Temperature ( Tn ) = Y - intercept + ( Temperature of any one of the first to n - th zones * a ) + ( Power ratio of the first zone * b 1 ) + ( Power ratio of the second zone * b 2 ) + … + ( Power ratio of the n - th zone * bn ) + ( Current value supplied to the heating wire installed in the n - th zone * c ) + ( Resistance vlaue for the other one of the first n - th zones * d ) + ( Resistance value for the n - th zone * e ) \qquad 〈 Mathematical Formula 1 〉$$
in Mathematical Formula 1, Y-intercept, a, b, c, d, and e are the coefficients.

7. The method of claim 1, further comprising:
placing a wafer TC capable of measuring the temperature of the first to n-th zones on the heater and acquiring the measured temperature.

8. An apparatus for processing a substrate through a heater that heats the substrate to perform a semiconductor process, comprising:
a database storing at least one independent variable and a dependent variable in association with each other;
a correlation formula storage unit storing a correlation formula of the independent variable and the dependent variable;
a calculation unit calculating a coefficient included in the correlation formula through regression analysis on the independent variable and the dependent variable;
a temperature control mechanism including a Kalman filter calculating an estimated temperature from a predicted temperature; and
a measuring mechanism acquiring a measurement value corresponding to the independent variable,
wherein the calculation unit inputs the measurement value into the correlation expression and calculates the predicted temperature of the heater.

9. The apparatus of claim 8, wherein the heater includes first to n-th zones (n=2, 3, . . . , m, m is an integer),
wherein the independent variable includes at least one of a temperature of any one of the first to n-th zones, a power ratio of the first to n-th zones, a current value supplied to a heating wire installed in a zone for which the predicted temperature is to be calculated, a resistance value for another one of the first to n-th zones, and a resistance value for a zone for which the predicted temperature is to be calculated.

10. The apparatus of claim 9, wherein the correlation formula for calculating the predicted temperature (Tn) for the n-th zone is expressed by the following <Mathematical Formula 1>:
$$Predicted Temperature ( Tn ) = Y - intercept + ( Temperature of any one of the first to n - th zones * a ) + ( Power ratio of the first zone * b 1 ) + ( Power ratio of the second zone * b 2 ) + … + ( Power ratio of the n - th zone * bn ) + ( Current value supplied to the heating wire installed in the n - th zone * c ) + ( Resistance vlaue for the other one of the first n - th zones * d ) + ( Resistance value for the n - th zone * e ) \qquad 〈 Mathematical Formula 1 〉$$
in Mathematical Formula 1, Y-intercept, a, b, c, d, and e are the coefficients.

11. The method of claim 4, wherein the correlation formula for calculating the predicted temperature (Tn) for the n-th zone is expressed by the following <Mathematical Formula 1>:
$$Predicted Temperature ( Tn ) = Y - intercept + ( Temperature of any one of the first to n - th zones * a ) + ( Power ratio of the first zone * b 1 ) + ( Power ratio of the second zone * b 2 ) + … + ( Power ratio of the n - th zone * bn ) + ( Current value supplied to the heating wire installed in the n - th zone * c ) + ( Resistance vlaue for the other one of the first n - th zones * d ) + ( Resistance value for the n - th zone * e ) \qquad 〈 Mathematical Formula 1 〉$$
in Mathematical Formula 1, Y-intercept, a, b, c, d, and e are the coefficients.

12. The method of claim 5, wherein the correlation formula for calculating the predicted temperature (Tn) for the n-th zone is expressed by the following <Mathematical Formula 1>:
$$Predicted Temperature ( Tn ) = Y - intercept + ( Temperature of any one of the first to n - th zones * a ) + ( Power ratio of the first zone * b 1 ) + ( Power ratio of the second zone * b 2 ) + … + ( Power ratio of the n - th zone * bn ) + ( Current value supplied to the heating wire installed in the n - th zone * c ) + ( Resistance vlaue for the other one of the first n - th zones * d ) + ( Resistance value for the n - th zone * e ) \qquad 〈 Mathematical Formula 1 〉$$
in Mathematical Formula 1, Y-intercept, a, b, c, d, and e are the coefficients.
